(19) United States
(12) Patent Application Publication
(10) Pub. No.: US 2025/0268105 A1
(43) Pub. Date: Aug. 21, 2025

(54) PIEZOELECTRIC MATERIAL DELIVERY DEVICES AND MATERIAL DELIVERY SYSTEMS WITH PIEZOELECTRIC MATERIAL DELIVERY DEVICES

(71) Applicant: Toyota Research Institute, Inc., Los Altos, CA (US)

(72) Inventors: Steven B.J. Torrisi, Berkeley, CA (US); Joseph Harold Montoya, Berkeley, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/582,768

(22) Filed: Feb. 21, 2024

(51) Int. Cl. H10N 30/20; H10N 30/80

(52) U.S. Cl. CPC H10N 30/20; H10N 30/802

(57) ABSTRACT

A material delivery device includes a piezoelectric layer and an additive material disposed on the piezoelectric layer such that activation of the piezoelectric layer sheds the additive material into a liquid. A voltage source configured to activate the piezoelectric layer, and a controller configured to command the voltage source to activate the piezoelectric layer can be included. The voltage source can be in communication with and configured to activate and de-active the piezoelectric layer, the controller can be in communication with and configured to command the voltage source, and a sensor in communication and configured to transmit a signal to the controller can be included.

### TECHNICAL FIELD

The present disclosure generally relates to material delivery devices, and particularly to material delivery devices for liquids.

### BACKGROUND

Chemical reactors, e.g., batch chemical reactors, continuous stirred-tank reactors, plug flow reactors, semi-batch reactors, and catalytic reactors, among others, generally include an enclosed volume in which at least one chemical reaction occurs. In addition, material delivery devices that add or provide predefined amounts of materials within such reactors are desired.

The present disclosure addresses issues related to material delivery devices for chemical reactors, among other issues related to material delivery devices.

### SUMMARY

This section provides a general summary of the disclosure, and is not a comprehensive disclosure of its full scope or all of its features.

In one form of the present disclosure, a material delivery device includes a piezoelectric layer and an additive material disposed on the piezoelectric layer such that activation of the piezoelectric layer sheds the additive material into a liquid.

In another form of the present disclosure, a material delivery device includes a piezoelectric layer, an additive material disposed on the piezoelectric layer such that activation of the piezoelectric layer sheds the additive material into a liquid, a voltage source configured to activate the piezoelectric layer, and a controller configured to command the voltage source to activate the piezoelectric layer.

In still another form of the present disclosure, material delivery includes a piezoelectric layer, an additive material disposed on the piezoelectric layer such that activation of the piezoelectric layer sheds the additive material into a liquid, a voltage source configured to activate the piezoelectric layer, a controller, and a sensor. The voltage source is in communication with and configured to activate and de-active the piezoelectric layer, the controller is in communication with and configured to command the voltage source, and the sensor is in communication and configured to transmit a signal to the controller.

Further areas of applicability and various methods of enhancing the disclosed technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1A illustrates a side cross-sectional view of a piezoelectric material delivery device according to the teachings of the present disclosure;

FIG. 1B illustrates the piezoelectric material delivery device in FIG. 1A with a substrate backing layer according to the teachings of the present disclosure;

FIG. 2A illustrates a side cross-sectional view of another piezoelectric material delivery device according to the teachings of the present disclosure;

FIG. 2B illustrates the piezoelectric material delivery device in FIG. 2A with a substrate backing layer according to the teachings of the present disclosure;

FIG. 3 illustrates a side cross-sectional view of still another piezoelectric material delivery device according to the teachings of the present disclosure;

FIG. 4 illustrates a side cross-sectional view of still yet another piezoelectric material delivery device according to the teachings of the present disclosure;

FIG. 5A illustrates the piezoelectric material delivery device in FIG. 1A prior to operation;

FIG. 5B illustrates the piezoelectric material delivery device in FIG. 5A after operating for a time t1;

FIG. 5C illustrates the piezoelectric material delivery device in FIG. 5A after operating for a time t2 greater than the time t1;

FIG. 6A illustrates the piezoelectric material delivery device in FIG. 3 prior to operation;

FIG. 6B illustrates the piezoelectric material delivery device in FIG. 3 after operating for a time t1;

FIG. 6C illustrates the piezoelectric material delivery device in FIG. 3 after operating for a time t2 greater than the time t1;

FIG. 7 illustrates a material delivery system with the piezoelectric material delivery device in FIG. 2A operating in a chemical reactor according to the teachings of the present disclosure;

FIG. 8 illustrates the material delivery system in FIG. 7 providing material to another chemical reactor according to the teachings of the present disclosure; and

FIG. 9 is a flow chart for a method of adding material to a liquid using a material delivery system according to the teachings of the present disclosure.

It should be noted that the figures set forth herein are intended to exemplify the general characteristics of piezoelectric material delivery devices and/or systems of the present technology, for the purpose of the description of certain aspects. These figures may not precisely reflect the characteristics of any given aspect, and are not necessarily intended to define or limit specific embodiments within the scope of this technology. Further, certain aspects may incorporate features from a combination of figures.

### DETAILED DESCRIPTION

The present teachings provide improved and/or enhanced devices and systems for providing, delivering, releasing, and/or injecting material into a liquid. The devices and/or systems include a piezoelectric layer and an additive material disposed on the piezoelectric layer. As used herein, the phrase “piezoelectric layer” refers to a layer of piezoelectric material, e.g., a piezoelectric crystal, configured to expand and contract when subjected to a voltage (e.g., an oscillating voltage). Non-limiting examples of a piezoelectric material include lead zirconate titanate (PbZr/TiO₃, also known as PZT), lead titanate (PbTiO₃), barium titanate (BaTiO₃), aluminum nitride (AlN), zinc oxide (ZnO), tourmaline quartz, langasite, lithium niobate (LiNbO₃), potassium niobate (KNbO₃), lead niobate (PbNbO₃), barium niobate (BaNbO₃), and sodium niobate (NaNbO₃), among others. And as used herein, the phrase “additive material” refers to a solid material that is or can be added to a liquid in order to take part in and/or assist in a chemical reaction. Non-limiting examples of an additive material include reactant materials, i.e., materials that participate in a chemical reaction, and catalyst materials, i.e., materials that catalyze but do not participate in a chemical reaction.

The devices and systems according to the teachings of the present disclosure release or shed additive material into a liquid. Particularly, a device according to the teachings of the present disclosure is at least partially immersed in a liquid and activation of the piezoelectric layer of the device results in the additive material being separated, e.g., being shed or sloughed, from the device and dispersed in the liquid.

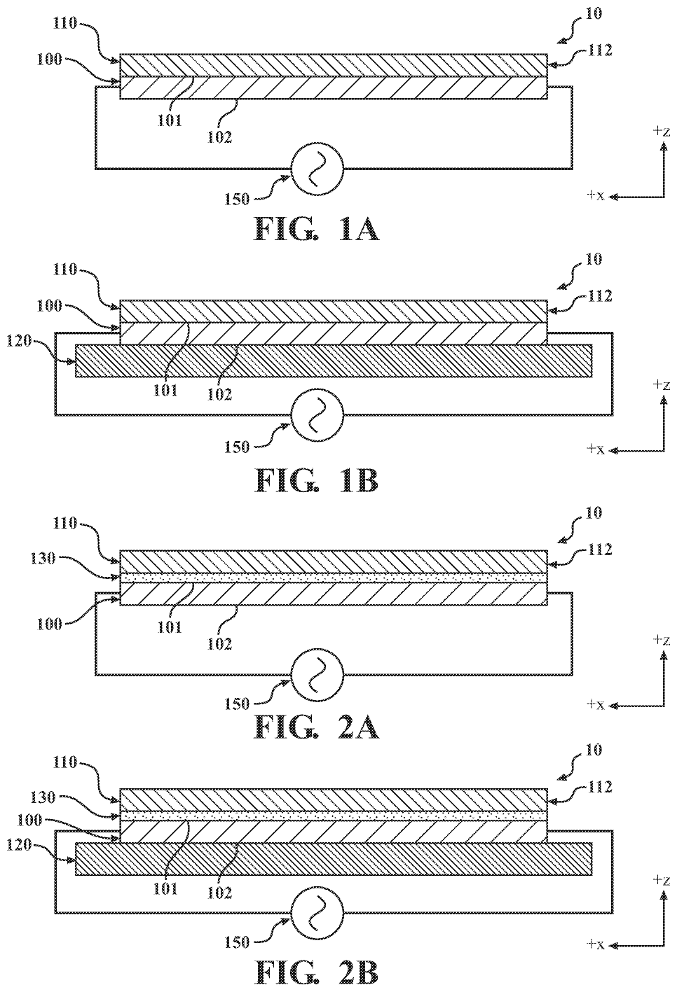

Referring to FIGS. 1A-1B a piezoelectric material delivery device 10 according to the teachings of the present disclosure is shown in FIG. 1A, and the piezoelectric material delivery device 10 with a substrate backing layer is shown in FIG. 1B. The piezoelectric material delivery device 10 includes a piezoelectric layer 100 and an additive material 110 disposed on the piezoelectric layer 100. In some variations, the additive material 110 is present as an additive material layer 112. The piezoelectric material delivery device 10 also includes an oscillating voltage source 150 in electric communication with the piezoelectric layer 100. In some variations, the oscillating voltage source 150 is a direct current voltage source configured to turn on and off at high frequencies, e.g., 60 Hz, 120 Hz. In the alternative, or in addition to, the oscillating voltage source 150 is an alternating voltage source that alternates between a positive voltage and a negative voltage at high frequencies. And in some variations, the oscillating voltage source 150 includes alternating voltage source that fluctuates current between two or more positive voltage values and/or two or more negative voltage values.

Not being bound by theory, applying a voltage to or across the piezoelectric layer 100 results in an electric field across the piezoelectric layer 100, which in turn produces a geometric strain in the piezoelectric layer 100. The geometric strain is proportional to the electric field and removing the voltage from the piezoelectric layer 100 removes the electric field such that the piezoelectric layer 100 returns to its original shape or size (i.e., the geometric strain is reversed). Accordingly, applying an oscillating voltage across the piezoelectric layer 100 results in an oscillating strain (vibration) of the piezoelectric layer 100. In addition, this vibration mechanism is used to remove additive material 110 the piezoelectric material delivery device 10 as described in greater detail below.

As illustrated in FIG. 1A, in some variations the piezoelectric material delivery device 10 includes the piezoelectric layer 100 with the additive material 110 disposed directly thereon (i.e., the additive material 110 is in direct contact with the piezoelectric layer 100), and a substrate backing layer 120 (FIG. 1B) is not included. For example, the piezoelectric layer 100 includes a first surface 101 onto which the piezoelectric layer 100 is disposed and in direct contact therewith, and a second surface 102 oppositely disposed and spaced apart from the first surface 101. In addition, the second surface 102 is a free surface, i.e., a surface that is not attached to and/or in direct contact with another layer of material. However, and as observed in FIG. 1B, in other variations, the piezoelectric material delivery device 10 includes a substrate backing layer 120 disposed on the second surface 102 of the piezoelectric layer 100. And in such variations, the piezoelectric layer 100 can be attached to the substrate backing layer 120, e.g., with an adhesive. In the alternative, the piezoelectric layer 100 can be in contact with, but not attached to, the substrate backing layer 120 such that the piezoelectric layer 100 is generally free to vibrate against the substrate backing layer 120. That is, the substrate backing layer 120 provides structural support but does inhibit vibration of the piezoelectric layer 100 except for frictional forces therebetween.

Referring to FIGS. 2A-2B, another piezoelectric material delivery device 12 according to the teachings of the present disclosure is shown in FIG. 2A, and the piezoelectric material delivery device 12 with a substrate backing layer is shown in FIG. 2B. Similar to the piezoelectric material delivery device 10 discussed above, a piezoelectric layer 100 and an additive material 110 disposed on the piezoelectric layer 100 are included. And in some variations, the additive material 110 is present as an additive material layer 112. The piezoelectric material delivery device 12 also includes the oscillating voltage source 150 in electric communication with the piezoelectric layer 100. However, unlike the piezoelectric material delivery device 10, the piezoelectric delivery device 10 includes an intermediate layer 130 disposed between the piezoelectric layer 100 and the additive material 110.

In some variations the intermediate layer 130 is a protective layer. For example, the intermediate layer 130 can prevent the piezoelectric layer 100 from coming into contact with a liquid that the piezoelectric material delivery device 12 is at least partially immersed in. In the alternative, or in addition to, the intermediate layer 130 provides enhanced adhesion to the piezoelectric layer 100 and/or the additive material 110. That is, the intermediate layer 130 can be included to ensure adequate bonding between the additive material 110 and the piezoelectric layer 100.

As observed in FIG. 2A, in some variations the piezoelectric material delivery device 10 includes the piezoelectric layer 100 with the additive material 110 disposed directly thereon (i.e., the additive material 110 is in direct contact with the piezoelectric layer 100), and a substrate backing layer 120 (FIG. 2B) is not included. For example, the piezoelectric layer 100 includes a first surface 101 onto which the intermediate layer 130 is disposed and in direct contact therewith, and a second surface 102 oppositely disposed and spaced apart from the first surface 101. In addition, the second surface 102 is a free surface, i.e., a surface that is not attached to and/or in direct contact with another layer of material. However, and as observed in FIG. 2B, in other variations, the piezoelectric material delivery device 10 includes a substrate backing layer 120 disposed on the second surface 102. And in such variations, the piezoelectric layer 100 can be attached to the substrate backing layer 120, e.g., with an adhesive. In the alternative, the piezoelectric layer 100 can be in contact with, but not attached to, the substrate backing layer 120 such that the piezoelectric layer 100 is generally free to vibrate against the substrate backing layer 120. That is, the substrate backing layer 120 provides structural support but does inhibit vibration of the piezoelectric layer 100 except for frictional forces therebetween.

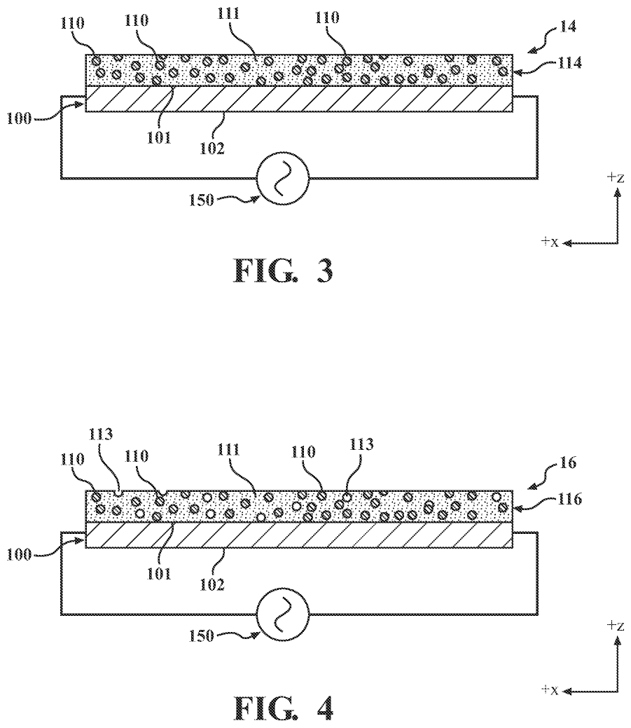

Referring to FIG. 3, yet another piezoelectric material delivery device 14 according to the teachings of the present disclosure is shown. Similar to the piezoelectric material delivery device 10 discussed above, a piezoelectric layer 100 and an additive material 110 disposed on the piezoelectric layer 100 are included. However, the additive material 110 is present in a composite layer 114. That is, the composite layer 114 includes the additive material 110 and a matrix material 111 (also referred to herein simply as “matrix 111”). The matrix 111 can serve as a carrier material and/or a carrier structure for the additive material 110, serve as a shedding material for the additive material as described in more detail below, and/or can serve as another additive material. And while FIG. 3 illustrates the piezoelectric material delivery device 14 with the composite layer 114 in direct contact with the piezoelectric layer 100 and a substrate backing layer 120 not included, in some variations an intermediate layer 130 (FIG. 2A) and/or a substrate backing layer 120 (FIG. 2B) can be included as part of the piezoelectric material delivery device 14.

Referring to FIG. 4, still yet another piezoelectric material delivery device 16 according to the teachings of the present disclosure is shown. Similar to the piezoelectric material delivery device 14 discussed above, the additive material 110 is present in a composite layer 116 that includes the additive material 110 and the matrix material 111. However, the matrix 111 includes pores 113, i.e., the matrix 111 is porous. In addition, the additive material 110 can be present within at least some of the pores 113, i.e., the additive material 110 can be embedded directly within the matrix material 111 and/or the pores 113. In some variations, the pores 113 are interconnected, while in other variations the pores 113 are isolated. Stated differently, in some variations the composite layer 116 has an open cell porous structure, while in other variations the composite layer 116 has a closed cell porous structure.

Similar to the composite layer 114, the matrix 111 can serve as a carrier material and/or a carrier structure for the additive material 110, serve as a shedding material for the additive material 110 as described in more detail below, and/or can serve as another additive material. And while FIG. 4 illustrates the piezoelectric material delivery device 16 with the composite layer 116 in direct contact with the piezoelectric layer 100 and a substrate backing layer 120 not included, in some variations an intermediate layer 130 (FIG. 2A) and/or a substrate backing layer 120 (FIG. 2B) can be included as part of the piezoelectric material delivery device 16.

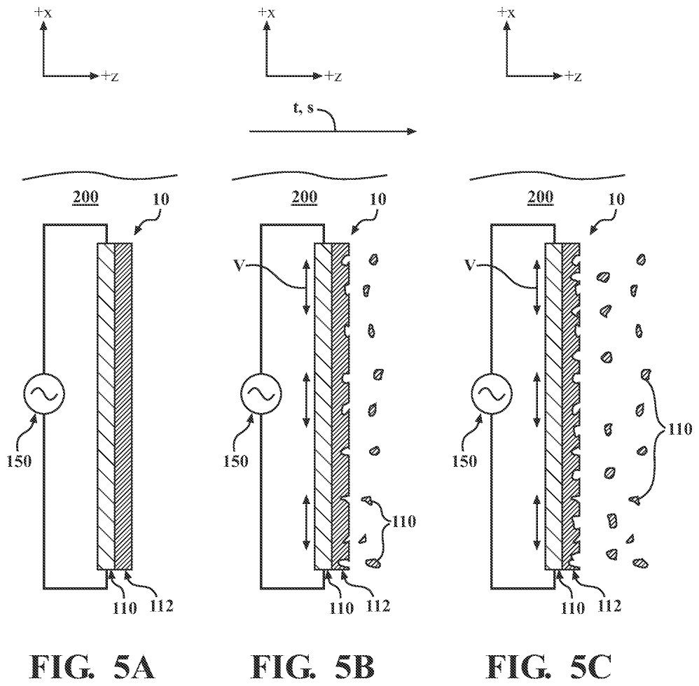

Referring now to FIGS. 5A-5C, operation of a piezoelectric material delivery device according to the teachings of the present disclosure is illustrated. Particularly, the piezoelectric material delivery device 10 is illustrated at least partially immersed in a liquid 200, e.g., a process liquid (i.e., a liquid that is part of a chemical process). It should be understood that the piezoelectric material delivery device 10 is shown as an exemplary example and that the voltage source 150 may or may not be immersed in the liquid 200.

Referring to FIG. 5A, the piezoelectric material delivery device 10 is a non-activated state such that the piezoelectric layer 100 is not vibrating and the additive material 110 remains as part of the additive material layer 112 that is disposed on the piezoelectric layer 100. However, and with reference to FIG. 5B, activation of the piezoelectric layer 100, i.e., applying an oscillating voltage to the piezoelectric layer 100 via the voltage source 150, results in an oscillating strain of the piezoelectric layer 100 (i.e., it vibrates). In addition, the oscillating strain is transferred to the additive material layer 112 such that additive material 110 separates from the additive material layer 112 and is dispersed in the liquid 200. And as illustrated in FIG. 5C, an increase in time of activation and/or magnitude of oscillating strain of the piezoelectric layer 100 as indicated by arrow ‘t,s’, results in an increase in the amount of additive material 110 that is separated from the additive material layer 112 and dispersed in the liquid 200.

Not being bound by theory, in some variations the additive material 110 separates from the additive material layer 112 via a mechanical fracture mechanism. That is, vibration of the piezoelectric layer 100 transferred to the additive material layer 112 results in multiple fractures within the additive material layer 112 (e.g., at crack initiation sites) such that individual particles of the additive material 110 separate (break free) from the additive material layer 112 and become completely dispersed (surrounded) in the liquid 200. In the alternative, or in addition to, in other variations the additive material layer 112 is at least partially soluble in the liquid 200 such that the additive material 110 of the additive material layer 112 at least partially dissolves in the liquid 200. And in such variations, vibration of the piezoelectric layer 100 transferred to the additive material layer 112 results in the additive material 110 being leeched and sloughed off of the additive material layer 112 and dispersed into the liquid 200 as shown in FIGS. 5B-5C.

In some variations, the additive material 110 is a catalyst material that catalyzes a reaction in the liquid 200, while in other variations the additive material 110 is a reactant material that becomes part of a chemical reaction in the liquid 200. Non-limiting examples of a catalyst material include IrO2, RuO2, MnSbO6, Pt, PtCo, PtNi, Pd, and NiCoOx, among others, and non-limiting examples of reactant materials include various hydrocarbons (e.g., C₂H₄, C₄H₁₀), amorphous or graphitic carbon, Zn, Co, Au, LiOH, and Li₂O, among others.

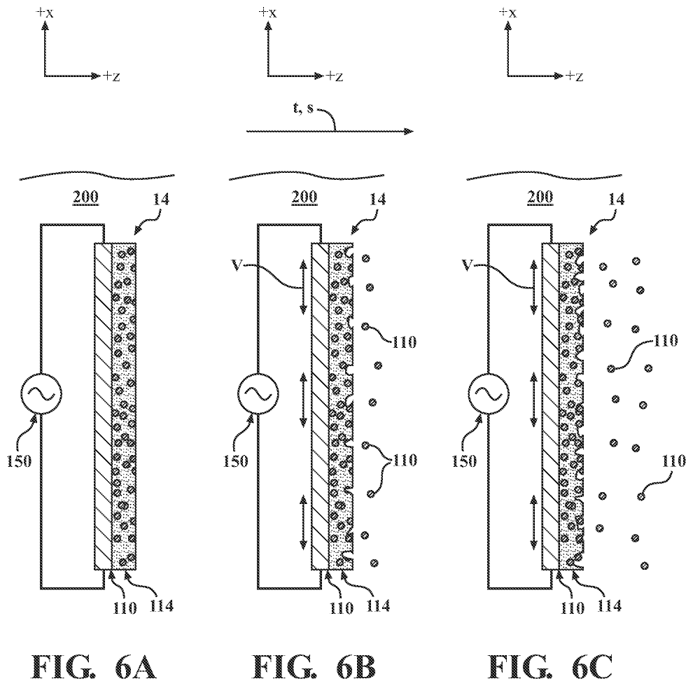

Referring now to FIGS. 6A-6C, operation of another piezoelectric material delivery device according to the teachings of the present disclosure is illustrated. Particularly, the piezoelectric material delivery device 14 is illustrated at least partially immersed in a liquid 200. It should be understood that the piezoelectric material delivery device 14 is shown as an exemplary example and that the voltage source 150 may or may not be immersed in the liquid 200.

Referring to FIG. 6A, the piezoelectric material delivery device 14 is a non-activated state such that the piezoelectric layer 100 is not vibrating and the additive material 110 remains intact with the composite layer 114 that is disposed on the piezoelectric layer 100. However, and with reference to FIG. 6B, activation of the piezoelectric layer 100 via the voltage source 150 results in an oscillating strain of the piezoelectric layer 100 (i.e., it vibrates), and such oscillating strain is transferred to the composite layer 114 such that the additive material 110 separates from the composite layer 114 and is dispersed in the liquid 200. And as illustrated in FIG. 6C, an increase in time of activation and/or magnitude of oscillating strain of the piezoelectric layer 100 as indicated by arrow ‘t,s’, results in an increase in the amount of additive material 110 that is separated from the composite layer 114 and dispersed in the liquid 200.

Not being bound by theory, in some variations the additive material separates from the composite layer 114 via a mechanical fracture mechanism. That is, vibration of the piezoelectric layer 100 transferred to the composite layer 114 results in multiple fractures within the composite layer 114 (e.g., at crack initiation sites) such that individual particles of the additive material 110 separate (break free) from the composite layer 114 and become completely dispersed (surrounded) in the liquid 200. In some variations, individual particles (pieces) of the matrix 111 also separate from the composite layer 114 and become completely dispersed in the liquid 200.

In the alternative, or in addition to, in other variations the composite layer 114, i.e., the matrix 111, is at least partially soluble in the liquid 200. And in such variations, vibration of the piezoelectric layer 100 transferred to the composite layer 114 results in the additive material 110 being sloughed off of the composite layer 114 and dispersed into the liquid 200. In addition, use of the composite layer 116 with pores 113 can provide enhanced (i.e., an increase) delivery of the additive material 110 via the flow of the liquid 200 into the pores 113, which in turn increases the dissolution of the matrix 111.

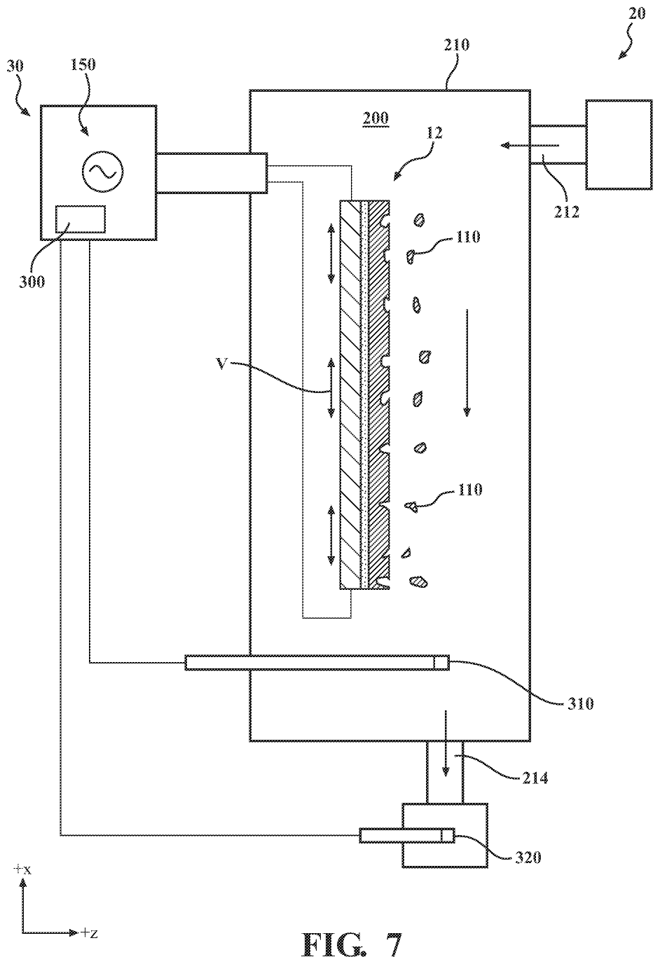

Referring to FIG. 7, a reactor 20 with a material delivery system 30 is shown. The reactor 20 includes a container 210, an inlet 212 into the container 210, and an outlet 214. The material delivery system 30 includes a piezoelectric material delivery system illustratively shown as the piezoelectric material delivery system 12, a controller 300 in communication with the voltage source 150, and one or more sensors 310, 320 in communication with the controller 300. Liquid 200 can enter the container 210 via the inlet 212 and exit the container 210 via the outlet 214.

During operation, the controller 300 commands the voltage source 150 to activate the piezoelectric layer 100 (FIG. 2A) of the piezoelectric material delivery device 12 such that additive material 110 is separated from the additive material layer 112 and immersed in the liquid 200 as described above. In addition, the one or more sensors 310, 320 transmit(s) signals to the controller 300, the signals being a function of a property of the liquid 200, and the controller commands the voltage source 150 to stop activating the piezoelectric layer 100 when a predefined signal value is received from the one or more sensors 310, 320.

For example, in some variations the additive material 110 participates in and/or catalyzes an exothermic chemical reaction within the liquid 200 such that a temperature of the liquid 200 increases. And in such variations, progress of the exothermic chemical reaction can be monitored via the temperature of the liquid 200. Accordingly, the one or more sensors 310, 320 can be a temperature sensor(s) and the controller 300 can command the voltage source 150 to continue activating the piezoelectric layer 100 or command the voltage source 150 to stop activating the piezoelectric layer 100 as a function of the temperature signals received from the one or more sensors 310, 320.

In other variations, the additive material 110 participates in and/or catalyzes a chemical reaction within the liquid 200 such that a pH of the liquid 200 either increases or decreases. And in such variations, progress of the chemical reaction can be monitored via the pH of the liquid 200. Accordingly, the one or more sensors 310, 320 can be a pH sensor(s) and the controller 300 can command the voltage source 150 to continue activating the piezoelectric layer 100 or command the voltage source 150 to stop activating the piezoelectric layer 100 as a function of pH signals received from the one or more sensors 310, 320.

In yet other variations, the additive material 110 participates in and/or catalyzes a chemical reaction within the liquid 200 such that an electrical current flowing through the liquid 200 (i.e., the electrical conductivity of the liquid 200) either increases or decreases. And in such variations, progress of the chemical reaction can be monitored via the electric conductivity of the liquid 200. Accordingly, the one or more sensors 310, 320 can be electrical conductivity sensor(s) and the controller 300 can command the voltage source 150 to continue activating the piezoelectric layer 100 or command the voltage source 150 to stop activating the piezoelectric layer 100 as a function of electrical conductivity signals received from the one or more sensors 310, 320.

In still other variations, the additive material 110 participates in and/or catalyzes a chemical reaction within the liquid 200 such that a color of the liquid 200 either increases or decreases. And in such variations, progress of the chemical reaction can be monitored via the color of the liquid 200. Accordingly, the one or more sensors 310, 320 can be an optical sensor(s) and the controller 300 can command the voltage source 150 to continue activating the piezoelectric layer 100 or command the voltage source 150 to stop activating the piezoelectric layer 100 as a function of optical signals received from the one or more sensors 310, 320, e.g., as a function of an optical property (e.g., color, clarity, etc.) of the liquid 200.

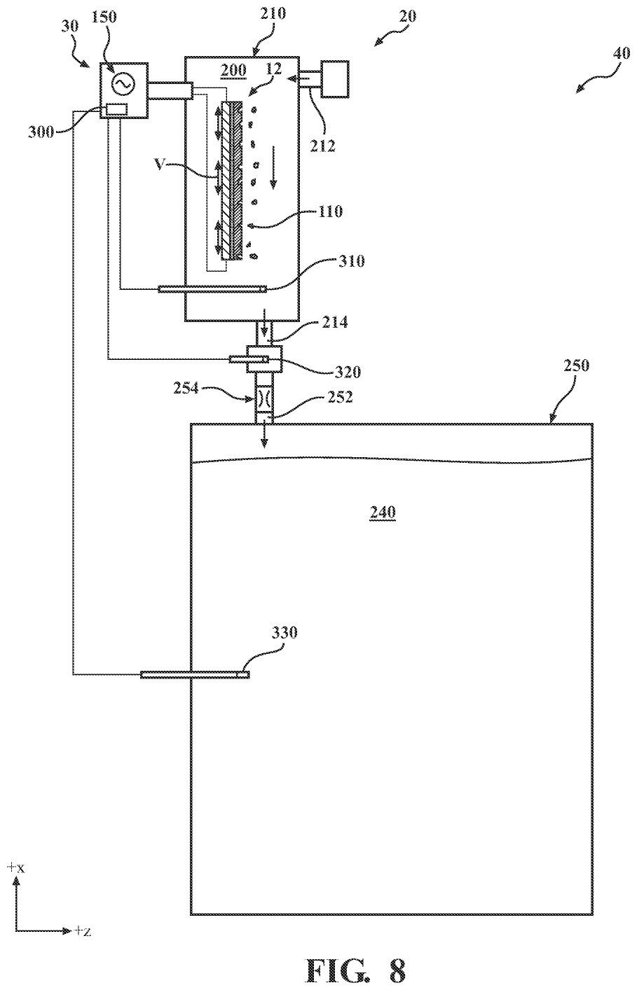

Referring to FIG. 8, a reactor 40 with the reactor 20 and the material delivery system 30 is shown. The reactor 40 includes a container 250 with an inlet 252 with a valve 254. The material delivery system 30 is as described above and the reactor 20 provides processed liquid 220p to the container 250, where the processed liquid 220p reacts with a liquid 240. Stated differently, the reactor 20 serves as a feedstock source. In addition, the material delivery system 30 includes a sensor 330 in communication with the liquid 240.

During operation, the controller 300 commands the voltage source 150 to activate the piezoelectric layer 100 (FIG. 2A) of the piezoelectric material delivery device 12 such that additive material 110 is separated from the additive material layer 112 and immersed in the liquid 200 as described above. In addition, the one or more sensors 310, 320 transmit(s) signals to the controller 300, the signals being a function of a property of the liquid 200, and the controller commands the voltage source 150 to stop activating the piezoelectric layer 100 when a predefined signal value is received from the one or more sensors 310, 320 as described above.

In the alternative, or in addition to, the processed liquid 220p is provided to the container 250 and the controller commands the controller commands the voltage source 150 to stop activating the piezoelectric layer 100 when a predefined signal value is received from the sensor 330. That is, the controller 300 monitors the liquid 240, and based on one or more properties of the liquid 240, commands the voltage source 150 to continue activating the piezoelectric layer 100 and commands the voltage source 150 to stop activating the piezoelectric layer 100.

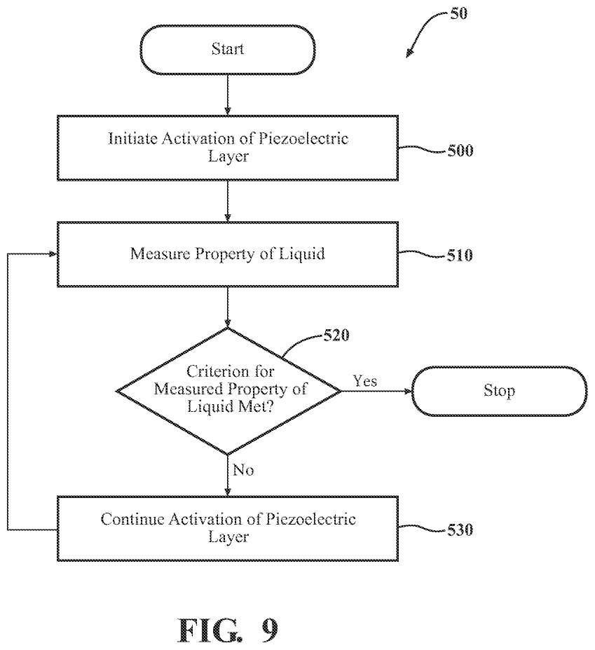

Referring to FIG. 9, and with reference to FIG. 6, a method 50 of adding material to a liquid using a material delivery system according to the teachings of the present disclosure is shown. The method 50 includes the controller 300 commanding the voltage source 150 to activate the piezoelectric layer 100 at 500 and measuring a property of the liquid at 510, e.g., by using the one or more sensors 310, 320. The controller 300 determines if a criterion or criteria for the measured property of the liquid 200 has been met at 520. For example, and based on signals received from the one or more sensors 310, 320, the controller 300 determines (e.g., from a lookup table, algorithm, etc.) if a predefine value (e.g., a temperature value, a pH value, a color value, etc.) of the measured property of the liquid 200 has been met. In the event that the criterion or criteria for the measured property of the liquid 200 has not been met at 520, the method proceeds to 530 where the controller 300 continues to command the voltage source 150 to activate the piezoelectric layer 100 and to 510 where the property of the liquid is measured. This cycle, i.e., 510-520-530-510 continues until the criterion or criteria for the measured property of the liquid 200 has been met at 520, and then the method 50 stops.

The preceding description is merely illustrative in nature and is in no way intended to limit the disclosure, its application, or uses. As used herein, the phrase at least one of A, B, and C should be construed to mean a logical (A or B or C), using a non-exclusive logical “or.” It should be understood that the various steps within a method may be executed in different orders without altering the principles of the present disclosure. Disclosure of ranges includes disclosure of all ranges and subdivided ranges within the entire range.

The headings (such as “Background” and “Summary”) and sub-headings used herein are intended only for general organization of topics within the present disclosure, and are not intended to limit the disclosure of the technology or any aspect thereof. The recitation of multiple embodiments having stated features is not intended to exclude other embodiments having additional features, or other embodiments incorporating different combinations of the stated features.

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that an embodiment can or may comprise certain elements or features does not exclude other embodiments of the present technology that do not contain those elements or features.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk, C++, Python, or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one aspect, or various aspects means that a particular feature, structure, or characteristic described in connection with an embodiment or particular system is included in at least one embodiment or aspect. The appearances of the phrase “in one aspect” (or variations thereof) are not necessarily referring to the same aspect or embodiment. It should also be understood that the various method steps discussed herein do not have to be carried out in the same order as depicted, and not each method step is required in each aspect or embodiment.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations should not be regarded as a departure from the disclosure, and all such modifications are intended to be included within the scope of the disclosure. In addition, Attachment A, filed with the present disclosure, is incorporated herein in its entirety by reference.

What is claimed is:

1. A material delivery device comprising:
a piezoelectric layer; and
an additive material disposed on the piezoelectric layer such that activation of the piezoelectric layer sheds the additive material into a liquid.

2. The material delivery device according to claim 1, wherein the additive material is in direct contact with the piezoelectric layer.

3. The material delivery device according to claim 1 further comprising an intermediate layer between the additive material and the piezoelectric layer.

4. The material delivery device according to claim 1, wherein the additive material is at least partially within a composite layer disposed on the piezoelectric layer.

5. The material delivery device according to claim 4, wherein the composite layer is a porous composite layer.

6. The material delivery device according to claim 1 further comprising a voltage source, a controller, and a sensor, wherein the voltage source is in communication with and configured to activate and de-active the piezoelectric layer, the controller is in communication with and configured to command the voltage source, and the sensor is in communication and configured to transmit a signal to the controller.

7. The material delivery device according to claim 6, wherein the sensor is configured to transmit the signal as a function of at least one of a pH of a liquid, a temperature of a liquid, an optical property of a liquid, or an electrical current in a liquid.

8. The material delivery device according to claim 7 further comprising a container, wherein the piezoelectric layer and the additive material disposed on the piezoelectric layer are positioned within the container.

9. The material delivery device according to claim 8 further comprising a process liquid in the container, wherein the piezoelectric layer and the additive material disposed on the piezoelectric layer are disposed in the process liquid.

10. A material delivery device comprising:
a piezoelectric layer;
an additive material disposed on the piezoelectric layer such that activation of the piezoelectric layer sheds the additive material into a liquid;
a voltage source; and
a controller.

11. The material delivery device according to claim 10, wherein the voltage source is in communication with and configured to activate the piezoelectric layer, and the controller is in communication with and configured to command the voltage source to active the piezoelectric layer and to command the voltage source to de-active the piezoelectric layer.

12. The material delivery device according to claim 10, wherein the additive material is in direct contact with the piezoelectric layer.

13. The material delivery device according to claim 10 further comprising an intermediate layer between the additive material and the piezoelectric layer.

14. The material delivery device according to claim 10, wherein the additive material is at least partially within a composite layer disposed on the piezoelectric layer.

15. The material delivery device according to claim 14, wherein the composite layer is a porous composite layer.

16. The material delivery device according to claim 10 further comprising a sensor configured to transmit a signal to the controller, wherein the signal comprises at least one of a pH signal of a liquid, a temperature signal of a liquid, an optical signal of a liquid, or an electrical current signal of a liquid.

17. A material delivery device comprising:
a piezoelectric layer;
an additive material disposed on the piezoelectric layer such that activation of the piezoelectric layer sheds the additive material into a liquid; and
a voltage source, a controller, and a sensor, wherein the voltage source is in communication with and configured to activate and de-active the piezoelectric layer, the controller is in communication with and configured to command the voltage source, and the sensor is in communication and configured to transmit a signal to the controller.

18. The material delivery device according to claim 17, wherein the additive material is in direct contact with the piezoelectric layer.

19. The material delivery device according to claim 17 further comprising an intermediate layer between the additive material and the piezoelectric layer.

20. The material delivery device according to claim 17, wherein the additive material is at least partially within a composite layer disposed on the piezoelectric layer.
